(19) United States
(12) Patent Application Publication
(10) Pub. No.: US 2007/0224854 A1
(43) Pub. Date: Sep. 27, 2007

(54) Memory module, method of manufacturing a memory module and computer system

(76) Inventors: Abdallah Bacha, Muenchen (DE); Siva Raghuram, Germering (DE)

Correspondence Address: EDELL, SHAPIRO & FINNAN, LLC, 1901 RESEARCH BLVD., SUITE 400, ROCKVILLE, MD, 20850, US

(21) Appl. No.: 11/389,541

(22) Filed: Mar. 27, 2006

(51) Int. Cl. H05K 1/00

(52) U.S. Cl. 439/79

(57) ABSTRACT

A memory module includes a first pc-board with a plurality of memory chips assembled thereon and with a second pc-board with a second plurality of memory chips assembled thereon. The first pc-board and the second pc-board are connected via first and second connectors placed on the surfaces of the first and second pc-boards.

### FIELD OF THE INVENTION

The invention relates to memory modules and the formation of memory modules for a computer system.

### BACKGROUND

Memory requirements of computer systems are increasing day by day. In order to get higher memory densities a possibility is to place a higher number of memory chips, for example chips with dynamic random access memory (DRAM) on a pc-board. DRAM is a type of random access memory that stores each bit of data in a separate capacitor. Due to standards, the physical space in computer systems is limited. So in order to place a higher number of DRAMs, they have to be stacked or placed on separate pc-boards attached to the main pc-board (motherboard). However, stacking DRAMs is expensive and it is difficult to manufacture separate pc-boards and using flexible cables to connect them.

### SUMMARY

In accordance with a first embodiment of the present invention, a memory module comprises a first pc-board with a first plurality of memory chips assembled thereon and with a first connector placed on a surface of the first pc-board, and a second pc-board with a second plurality of memory chips assembled thereon and with a second connector placed on the surface of the second pc-board, where the first and the second connector are electrically and mechanically connected. An advantage of an embodiment of this present invention is that it is easy to manufacture such memory modules, since connectors are easily placed on surfaces of pc-boards, for example, by using surface mountable connectors (SMT connectors).

In another embodiment of the present invention, the connector is placed between two rows of DRAMs or more. Such placement of the connection in this manner provides several advantages compared to the placement on the bottom edge side of such pc-board. For example, it is possible to use standard topology for data bus and pre-register command and address bus (C/A bus). Furthermore, it is possible to reduce the total data bus (DQ) and pre-register C/A capacitor nets and to reduce the number of stub resistors by half. So the costs for such pc-boards (which are also called dual inline memory modules (DIMM)) is reduced.

In a further embodiment of the present invention, more than two pc-boards are connected via connectors that are situated on surfaces of the pc-board. With this technique it is possible to build memory modules, which need only a limited amount of physical space but have an enhanced memory capacity.

In another embodiment of the invention, two pc-boards with memory chips assembled thereon are connected and placed in parallel, so that only a limited amount of physical space is used inside a computer system.

A further advantage of an embodiment of the present invention is to build the connectors on the pc-boards by connector parts that are arranged in such a way, that contacts of an edge connector of the first pc-board are arranged correspondingly. With this arrangement it is possible to keep the distances between the contacts of the edge connector to the contacts of the connectors as short as possible, thereby reducing additional resistances and residual capacities. A further advantage of the present invention is that only one edge connector is used by a memory module comprising two or more pc-boards with memory chips so that only one socket of the motherboard of the computer system is occupied after inserting such a memory module.

The above and still further features and advantages of the present invention will become apparent upon consideration of the following detailed description of specific embodiments thereof, particularly when taken in conjunction with the accompanying drawings wherein like reference numerals in the various figures are utilized to designate like components.

### BRIEF DESCRIPTION OF THE DRAWINGS

FIG. 1a schematically depicts two pc-boards with connectors in a view seeing assembled surfaces of the pc-boards before connecting them in a first embodiment of the invention.

FIG. 1b schematically depicts a side view of a memory module of two pc-boards, assembled with memory chips, which are connected in the first embodiment of the invention.

FIG. 2a schematically depicts two assembled pc-boards with connectors showing the surfaces of the pc-boards before connecting them together in a second embodiment of the invention.

FIG. 2b schematically depicts a side view of a memory module of two connected pc-boards in the second embodiment of the invention.

FIG. 3a schematically depicts three pc-boards before being connected in a third embodiment of the invention.

FIG. 3b schematically depicts a side view of a memory module of three pc-boards being connected in the third embodiment of the invention.

FIG. 4a schematically depicts three pc-boards before being connected in a fourth embodiment of the invention.

FIG. 4b schematically depicts a side view of a memory module of three pc-boards being connected in the fourth embodiment of the invention.

FIG. 5a depicts a data(DQ)-bus topology for connecting the memory chips of a DIMM while using the connectors at one side of the DIMM in accordance with the invention.

FIG. 5b depicts a Pre-Register C/A-Bus topology for connecting the registers in an embodiment with a connector at one side of the DIMM in accordance with the invention.

FIG. 6a depicts a data(DQ)-bus topology for connecting the memory chips of a DIMM in an embodiment with a connector between two rows in a DIMM in accordance with the invention.

FIG. 6b depicts a Pre-Register C/A-Bus topology for connecting registers of a DIMM in an embodiment with a connector between two rows of memory chips in accordance with the invention.

FIG. 7 schematically depicts a computer system with a memory module connected to a socket of a mother board in accordance with the invention.

### DETAILED DESCRIPTION

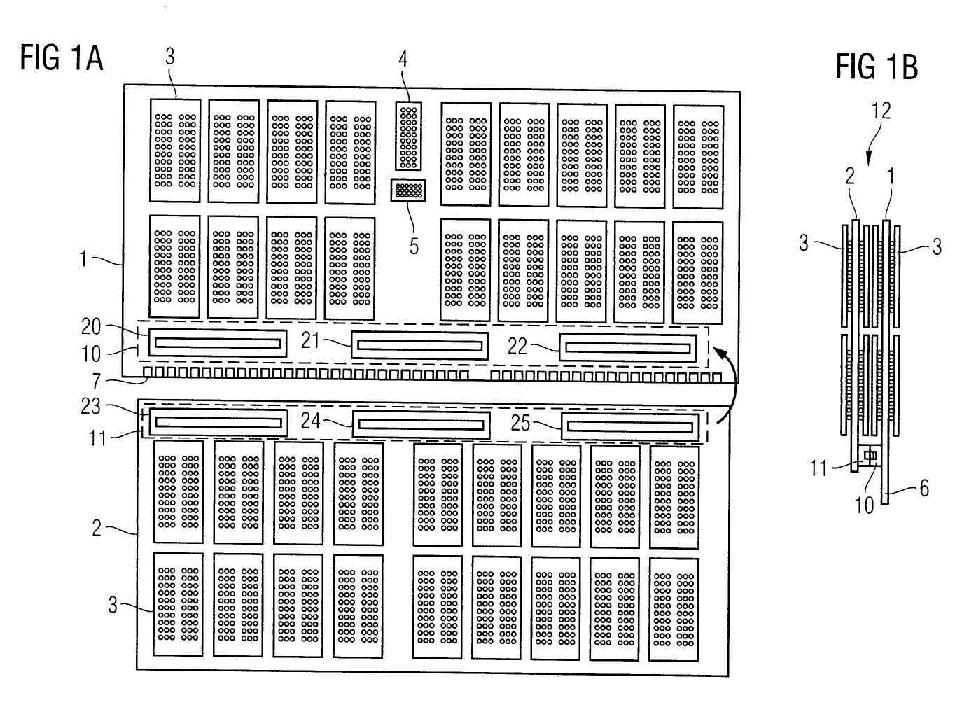

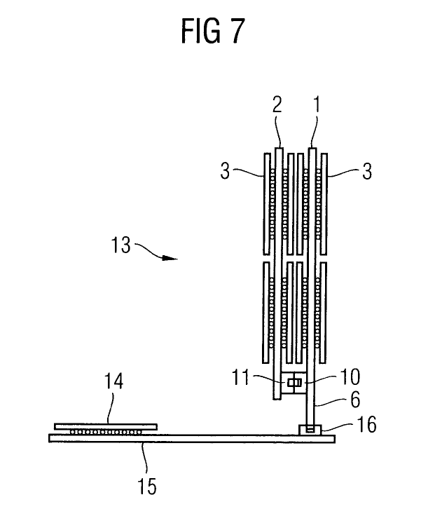

In FIG. 1a, a first pc-board 1 is depicted together with a second pc-board 2, where on the first pc-board 1 and the second pc-board 2 there are assembled with eighteen DRAMs 3 on the first pc-board 1 and eighteen DRAMs 3 on the pc-board 2. A pc-board with memory chips 3 assembled thereon is also called DIMM (dual in-line memory module) when a 64-bit data path is present and the contacts 7 are separated on each surface of the module, whereas a SIMM (single in-line module) has a 32-bit data path and the contacts on both surfaces of the pc-board are redundant. On the first pc-board 1 there is also assembled a register 4 and a phase locked loop (PLL) 5, which is used to generate clock signals in order to synchronize writing and reading operations of the DRAMs 3. On one edge of the first pc-board 1 there is shown an edge connector 6, including a plurality of contacts 7, which are used to contact the first pc-board 1 with a socket 16 that is situated on a motherboard 15 of a computer system 13 (depicted in FIG. 7). Between the contacts 7 there is also provided a notch without a contact 7, so that a user may insert the first pc-board 1 into the socket 16 of a motherboard 15 in the correct direction. The contacts 7 are used to contact the computer bus system of the motherboard 15 in order to provide the DRAMs 3 with data and with commands and addresses. The data is provided via a so-called DQ-bus and the commands and addresses are provided via a so-called C/A-bus. On the first pc-board there is provided a first connector 10 and correspondingly on the second pc-board 2 there is provided a second connector 11. The first connector 10 includes three connector parts 20, 21, 22 and the second connector 11 includes three connector parts 23, 24, 25. The connector parts 20, 22 at the left and the right side of the first pc-board 1 and the connector parts 23, 25 at the left and the right side of the second pc-board 2 are used to transfer signals of the data bus since the contacts 7 of the edge connector 7 in this region of the first pc-board 1 are used to contact the data bus of the motherboard (not shown). The connector parts 21, 24 in the middle of the pc-boards 1 and 2 are used to transfer signals of the C/A-bus, since the contacts 7 of the edge connector 6 in this region of the pc-board 1 are contacted to the C/A-bus of the motherboard 15. So, the distances of the contacts 7 to the connectors are small and thereby a complicated wiring scheme on the pc-board 1 is omitted.

In FIG. 1b, it can be seen how the first pc-board 1 with DRAMs 3 situated on both surfaces and the second pc-board 2 with also DRAMs 3 on both surfaces are connected via the first connector 10 and the second connector 11 so that they build a memory module 12, which can be inserted into a socket 16 of a motherboard 15 by a single edge connector 6. Since the first pc-board 1 and the second pc-board 2 are arranged in parallel, the whole memory module 12 will not need much more space than a single pc-board with DRAMs 3 and is therefore well suited for the restricted space, which is available in computer systems.

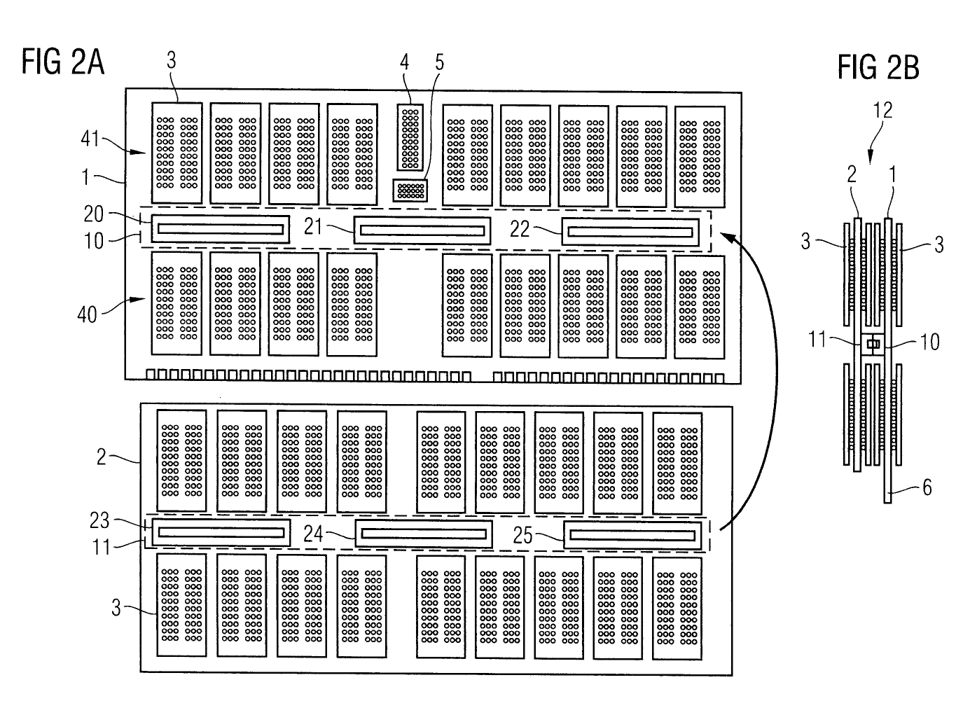

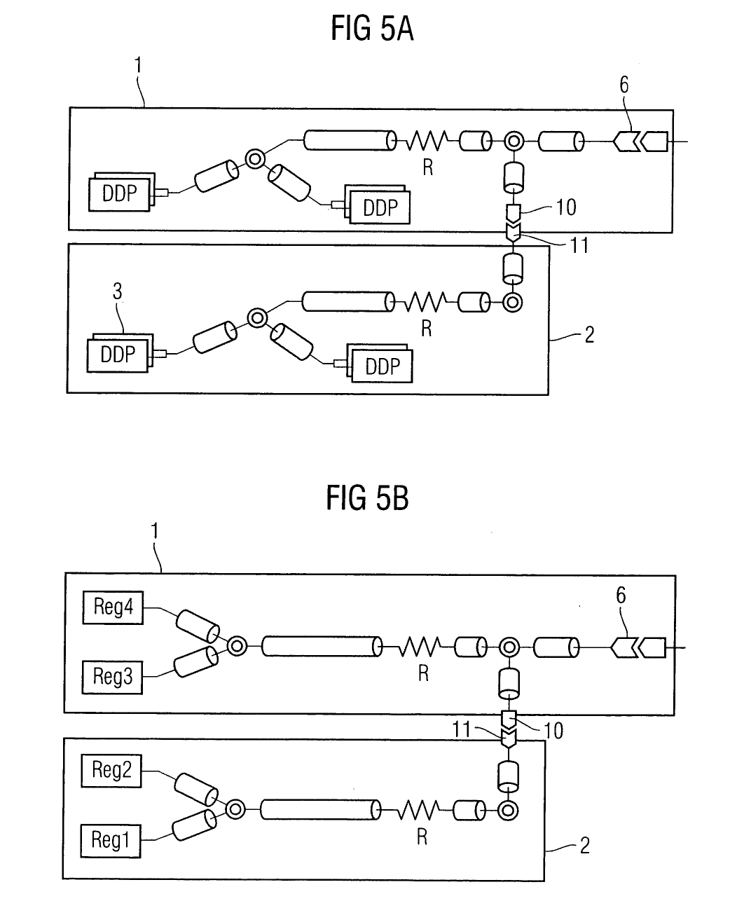

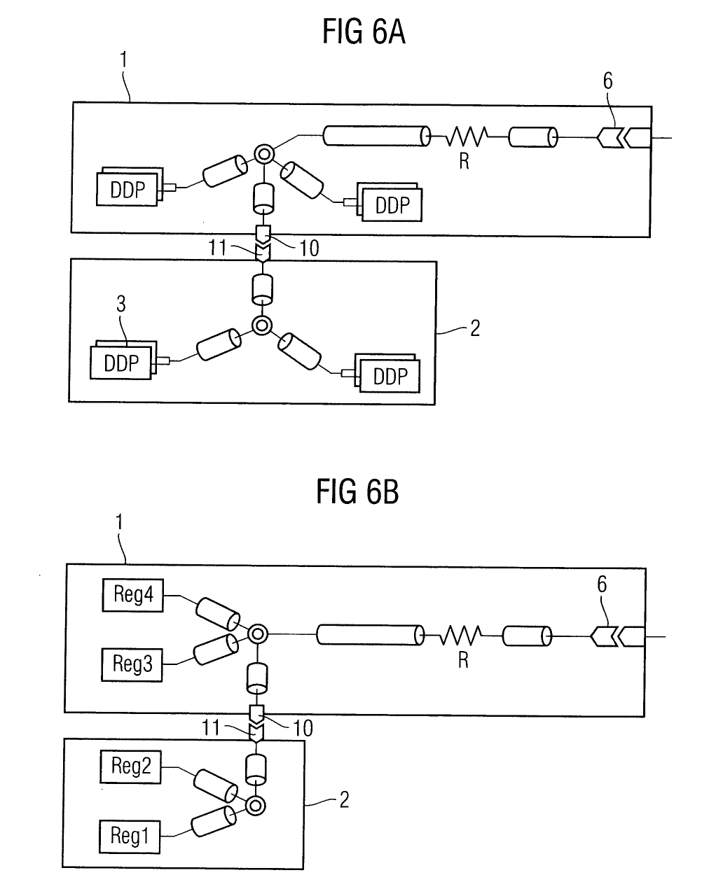

In FIG. 2a, another embodiment of the present invention is depicted. Before connecting a first pc-board 1 and a second pc-board 2 together their surfaces looks like it is depicted in FIG. 2a. In this embodiment the first connector 10 and the second connector 11 are situated between two rows 40, 41 of DRAMs 3 on both of the surfaces of the first pc-board 1 and the second pc-board 2. In FIG. 2b the first pc-board 1 and the second pc-board 2 are connected together via the first connector 10 and the second connector 11 also revealing the very compact form of this memory module 12, which can be inserted into the socket 16 of a motherboard 15 via the edge connector 6. The advantages of the arrangement of the first connector 10 and the second connector 11 between the two rows 40,41 of DRAMs 3 will be explained in more detail with reference to FIGS. 5 and 6.

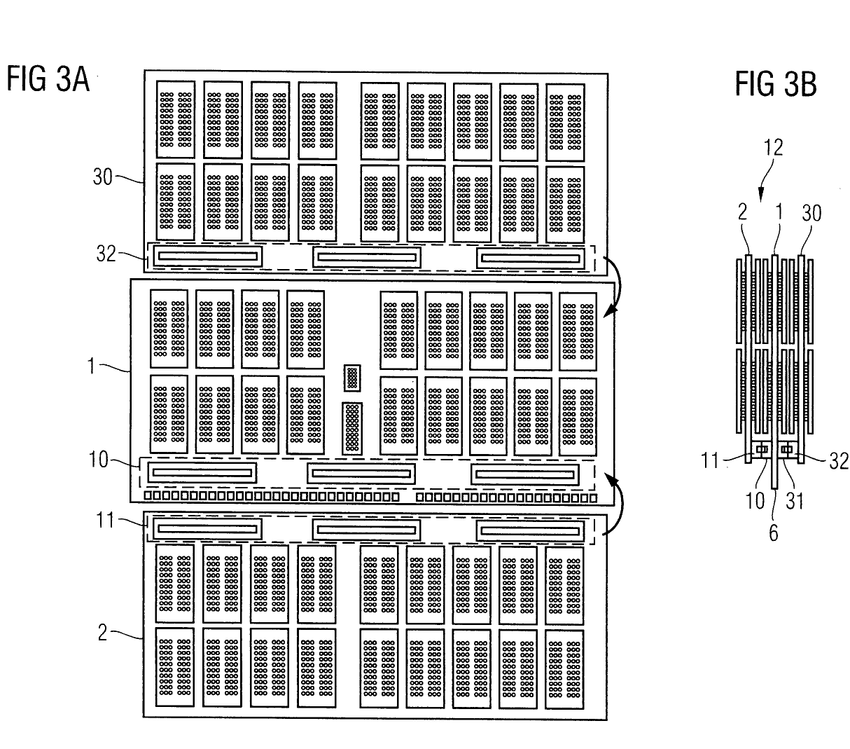

In FIG. 3a, a third pc-board 30 with a third connector 32 is used for further increasing the number of DRAMs 3 which are used in a memory module 12. For this embodiment a fourth connector 31 is used on the other surface of the first pc-board 1 (FIG. 3b) so that a mechanical and electrical connection between the first, second and third pc-board is established. In this embodiment the connectors 10, 11, 32 are situated below the rows of DRAMs 3.

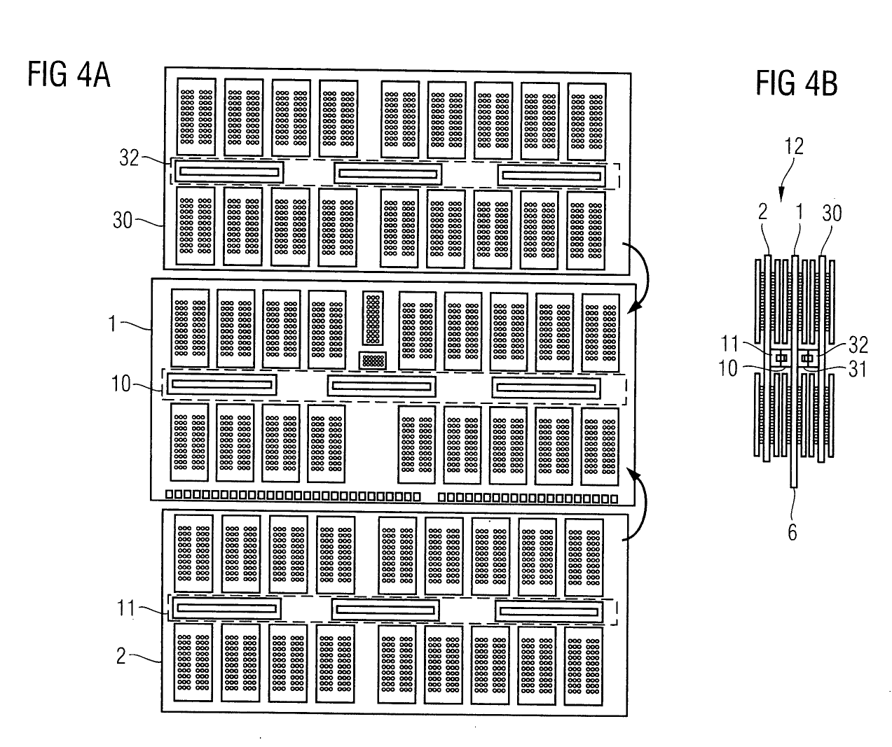

In FIG. 4a, the surfaces of the first pc-board 1, the second pc-board 2 and the third pc-board 30 are depicted. In this embodiment the first connector 10, the second connector 11 and the third connector 32 are situated between two rows of DRAMs 3. In FIG. 4b, a schematic side view is depicted of the three pc-boards 1, 2, 30, which are connected together.

In FIG. 5a there is shown a circuit diagram for contacting the DRAMs 3 (which in this case are built as dual die packages (DDP), wherein two chips are stacked one above another in order to increase memory capacity) via a first connector 10 and a second connector 11 which are situated at the bottom below the two rows of DRAMs 3 as it is shown in FIG. 1a. In FIG. 5b, the corresponding circuit diagram is shown for contacting the registers REG1, REG2, REG3, REG4 which are situated on either side of the first pc-board 1 and the pc-board 2. As can be seen from the electronic circuit diagrams there is a stub resistor R in both the first and the second pc-board.

In FIGS. 6a and 6b there are depicted the correspondent circuit diagrams for the embodiment with the first connector 10 and the second connector 11 situated between the two rows of DRAMs 3. As can be seen in this case there is no need for an additional stub resistor R in the second pc-board 2. Also the overall capacity on the second pc-board 2 is reduced due to shorter wirings on the second pc-board 2.

FIG. 7 schematically depicts a computer system 13, which includes a central processing unit 14 (CPU), which is assembled on a surface of a motherboard 15. The motherboard includes a socket 16, in which additional memory modules 12, as there are described in this application, may be inserted.

The invention may be embodied in other specific forms without departing from the spirit or essential characteristics thereof. The present embodiments are therefore to be considered in all respects as illustrative and not restrictive, the scope of the invention being indicated by the appending claims rather than by the foregoing description and all changes with come within the meaning and the range of equivalency of the claims are therefore intended to be embraced therein.

In particular, it will be apparent to one skilled in the art that various changes and modifications can be made therein without departing from the spirit and scope thereof. Accordingly, it is intended that the present invention covers the modifications and variations of this invention provided they come within the scope of the appended claims and their equivalents.

What is claimed:

1. A memory module comprising:
a first pc-board including a first plurality of memory chips assembled thereon and a first connector placed on a surface of the first pc-board;
a second pc-board including a second plurality of memory chips assembled thereon and a second connector placed on a surface of the second pc-board;
wherein the first and the second connectors are electrically and mechanically connected to each other.

2. The memory module of claim 1, wherein the plurality of memory chips are assembled in at least two rows on the first pc-board and the first connector is situated between the two rows.

3. The memory module of claim 1, wherein the plurality of memory chips are assembled in at least two rows on the second pc-board and the second connector is situated between the two rows.

4. The memory module of claim 1, wherein the first pc-board comprises an edge connector.

5. The memory module of claim 1, wherein the first pc-board and the second pc-board are oriented in parallel with respect to each other.

6. The memory module of claim 1, further comprising:
a third pc-board including a third plurality of memory chips assembled thereon and a third connector placed on a surface of the third pc-board;
wherein the first pc-board comprises a fourth connector on a surface of the first pc-board and the third pc-board and the first pc-board are electrically and mechanically connected to each other via the third and fourth connectors.

7. The memory module of claim 6, wherein the first and fourth connectors are situated on opposite surfaces of the first pc-board.

8. The memory module of claim 1, wherein the first and the second connectors are configured to transfer signals of a computer bus system.

9. The memory module of claim 8, wherein each of the first and second connectors includes separate connector parts, and each of the separate connector parts are configured to transfer signals of a different computer bus.

10. The memory module of claim 9, wherein the first pc-board comprises an edge connector that electrically connects the first pc-board to a computer bus system that includes different computer buses, and the connector part of the first pc-board that transfers signals of one of the computer buses is disposed in the vicinity of contacts of the edge connector that are configured to contact the one of the computer buses.

11. The memory module of claim 9, wherein the first pc-board comprises an edge connector that electrically connects the first pc-board to a computer bus system that includes different computer buses, and the connector parts that transfer signals of the different computer buses are arranged in the same order on the first and second pc-boards as the order of contacts of the edge connector that are configured to contact the different computer buses.

12. A memory module comprising:
a first pc-board including a plurality of memory chips assembled thereon and an edge connector; and
a second pc-board including a second plurality of memory chips assembled thereon;
wherein the first and the second pc-board are mechanically and electrically connected to each other and oriented in parallel with respect to each other.

13. The memory module of claim 12, further comprising:
a third pc-board including a third plurality of memory chips assembled thereon, wherein the third and the first pc-boards are mechanically and electrically connected to each other and oriented in parallel with respect to each other.

14. The memory module of claim 13, wherein the third and the second pc-boards are situated on opposite sides of the first pc-board.

15. The memory module of claim 12, further comprising:
further pc-boards including further pluralities of memory chips assembled thereon, wherein the further pc-boards are mechanically and electrically connected to each other and oriented in parallel with respect to each other.

16. A memory module comprising a pc-board including a plurality of memory chips assembled thereon in at least two rows on one of the surfaces of the pc-board and a first connector situated on a surface of the pc-board between the two rows.

17. The memory module of claim 16, wherein a further connector is disposed on the opposite surface of the pc-board.

18. The memory module of claim 17, wherein further memory chips are assembled in two rows on the opposite surface of the pc-board and the further connector is situated between the two rows of the further memory chips.

19. A memory module comprising:
a first pc-board with a first plurality of memory chips assembled thereon and a first means for connecting the first pc-board to another pc-board, the first means for connecting being disposed on a first surface of the first pc-board;
a second pc-board with a second plurality of memory chips assembled thereon and a second means for connecting the second pc-board to another pc-board, the second means for connecting being disposed on a surface of the second pc-board;
wherein the first and second pc-boards are electrically and mechanically connected to each other via the first and second means for connecting.

20. The memory module of claim 19, wherein the first plurality of memory chips are assembled in at least two rows on one surface of the first pc-board and the first means for connecting is situated between the two rows.

21. The memory module of claim 19, wherein the second plurality of memory chips are assembled in at least two rows on one surface of the second pc-board and the second means for connecting is situated between the two rows.

22. The memory module of claim 19, further comprising:
a third means for connecting the first pc-board to another pc-board, the third means for connecting being situated on a surface opposite to the first surface of the first pc-board; and
a third pc-board including a third plurality of memory chips assembled thereon and a fourth means for connecting the third pc-board to another pc-board, the fourth means for connecting being disposed on a surface of the third pc-board;
wherein the first and third pc-boards are electrically and mechanically connected via the third and fourth connecting means.

23. A method of manufacturing a memory module comprising:
assembling a first pc-board including memory chips on a surface of the first pc-board;
assembling a first connector on the surface of the first pc-board;
assembling a second pc-board including memory chips on a surface of the second pc-board;
assembling a second connector on the surface of the second pc-board; and
connecting the first and the second pc-boards to each other via the first and second connectors.

24. The method of claim 23, further comprising:
assembling a third pc-board including memory chips on a surface of the third pc-board;
assembling a third connector on the surface of the third pc-board;
assembling a fourth connector on a surface of the first pc-board; and
connecting the first and third pc-boards to each other via the third and fourth connectors.

25. The method of claim 23, wherein the memory chips are assembled on the first pc-board in at least two rows, and the first connector is disposed between the two rows.

26. The method of claim 23, wherein the memory chips are assembled on the second pc-board in at least two rows, and the second connector is disposed between the two rows.

27. The method of claim 23, further comprising:
providing connector parts that form the first connector, the connector parts being configured to transfer signals of different computer buses;
providing an edge connector for the first pc-board that contacts the first pc-board to a computer bus system that includes different computer buses;
assembling the connector parts in the vicinity of contacts of the edge connector such that each connector part contacts a respective computer bus.

28. A method of manufacturing a memory module comprising:
assembling a pc-board including memory chips in at least two rows on a first surface of the pc-board;
assembling a connector on the first surface of the pc-board between the two rows of memory chips.

29. The method of claim 28, further comprising:
assembling memory chips in at least two rows on a second surface of the pc-board that opposes the first surface; and
assembling a further connector on the second surface between the two rows of memory chips.

30. A computer system including the memory module of claim 1.

31. A computer system including the memory module of claim 12.

32. A computer system including the memory module of claim 16.

33. A computer system including the memory module of claim 19.
